(19) United States
(12) Patent Application Publication
(10) Pub. No.: US 2009/0211794 A1
(43) Pub. Date: Aug. 27, 2009

(54) Wiring board and manufacturing method therefor

(75) Inventor: Kouji Nakaie, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/379,287

(22) Filed: Feb. 18, 2009

(30) Foreign Application Priority Data
Feb. 26, 2008 (JP) 44503/2008

(51) Int. Cl. H05K 1/18; H05K 1/11; H05K 3/00; H05K 3/30

(52) U.S. Cl. 174/260; 174/262; 29/829; 29/832

(57) ABSTRACT

In order to provide a wiring board having a structure different from a conventional structure and a manufacturing method therefor, a wiring board (1) includes: a first principal surface (6a); a second principal surface (6b) being opposed to the first principal surface (6a); a plurality of wiring layers (81, 82, 83, and 84); and a through hole (30) piercing at least one set of neighboring wiring layers among the plurality of wiring layers in a lamination direction of the at least one set of neighboring wiring layers. The through hole (30) includes a flat surface (21) that has conductivity and is decoupled electrically into at least two blocks formed on its surface at least partially.

### BACKGROUND OF THE INVENTION

1. Field of the Invention

The present invention relates to a wiring board and a manufacturing method therefor. More specifically, the present invention relates to a wiring board having a plurality of wiring layers and a manufacturing method therefor.

2. Description of the Related Art

In a semiconductor device, a wiring board is used for mounting IC chips and for connecting the IC chips with each other or with external wirings. The wiring board usually includes a plurality of insulating layers and wiring layers, and through holes piercing the insulating layers and wiring layers.

FIG. 14 illustrates a conventional example in which surface mount components are mounted on a top surface of a wiring substrate having a multilayer structure, and another electronic component is mounted between terminals of the surface mount components. A wiring board 100 according to Conventional Example 1 includes a wiring substrate 106, through holes 130, a first surface wiring layer 181, a second surface wiring layer 184, a first electronic component 111, a second electronic component 112, and a surface mount component 105 as illustrated in FIG. 14. The surface mount component 105 and the first electronic component 111 are mounted on a first principal surface 106a of the wiring substrate 106, and the second electronic component 112 is mounted on a second principal surface 106b opposed to the first principal surface of the wiring substrate 106.

As to the first principal surface 106a of the wiring substrate 106, component connection lands are formed on the first surface wiring layer 181 for connecting the wiring substrate 106 with the first electronic component 111 electrically. Similarly, as to the second principal surface 106b of the wiring substrate 106, component connection lands are formed on the second surface wiring layer 184 for connecting the wiring substrate 106 with the second electronic component 112 electrically.

As to the wiring board 100 having the structure described above, the surface mount component 105 is connected with the first electronic component 111 electrically via a path of a dashed dotted line A of FIG. 14, for instance. In addition, the surface mount component 105 is connected with the second electronic component 112 electrically via a path of a dotted line B of FIG. 14.

In the structure of the wiring board 100 according to Conventional Example 1, it is clear from FIG. 14 that the distance between the terminal of the first electronic component 111 and the terminal of the surface mount component 105 cannot be decreased. The same is true for the distance between the terminal of the second electronic component 112 and the terminal of the surface mount component 105. If the surface mount component is not close to the electronic component, an inductance component of the wire connecting the surface mount component and the electronic component with each other increases so that the high frequency characteristic is deteriorated.

Therefore, another structure is proposed in which another electronic component connected to the terminal of the surface mount component is embedded in the wiring board instead of being mounted on the wiring board (see, for example, Japanese Patent Application Laid-open No. 2005-72415 and Japanese Patent Application Laid-open No. 2006-49457). FIG. 15A illustrates a schematic cross section of a wiring board 200 of a component embedded type described in Japanese Patent Application Laid-open No. 2006-49457 as Conventional Example 2, and FIG. 15B illustrates a partial plan view thereof. An electronic component 110 is embedded in the wiring board 200 as illustrated in the figure. The electronic component 110 is embedded in the wiring substrate 106, and hence the terminal of the electronic component 110 can be close to the terminal of the surface mount component (not shown).

However, in the wiring board 200 according to Conventional Example 2, a shape of a component connection land 131 that is connected to a terminal 110a of the electronic component 110 is like an arc in plan view as illustrated in FIG. 16. Therefore, the thickness of solder 133 becomes uneven depending on the place. For instance, a minimum distance D1 between the terminal corner portion of the terminal 110a of the electronic component 110 and the component connection land 131 is different from a minimum distance D2 between the middle of the side wall of the terminal 110a of the electronic component 110 and the component connection land 131 as illustrated in FIG. 16.

The component connection land 131, the solder 133 and the electronic component 110 are usually made of different materials. Therefore, the component connection land 131, the solder 133 and the electronic component 110 have different thermal capacity values. Consequently, when the solder is melted in a reflow furnace, uneven melted states of the solder may occur due to specific heat of the solder. Then, as the solder becomes a solid, the solder having a smaller thickness in the vicinity of the distance D1 is cooled by the component connection land 131 and the electronic component 110 and becomes a solid earlier than the solder in the vicinity of the distance D2. In this case, a crack may occur in the solder because of a volume difference between the melted state and the solid state. The occurrence of a crack may cause a solder poor connection. Thus, there is a problem that the solder poor connection occurs easily.

### SUMMARY OF THE INVENTION

A wiring board according to the present invention includes: a first principal surface; a second principal surface being opposed to the first principal surface; a plurality of wiring layers; and a through hole piercing at least one set of neighboring wiring layers among the plurality of wiring layers in a lamination direction of the at least one set of neighboring wiring layers. The through hole includes a flat surface that has conductivity and is decoupled electrically into at least two blocks formed on its surface at least partially.

According to the wiring board of the present invention, it is possible to provide the wiring board having a new structure different from the conventional structure. In the new structure, the flat surface having conductivity (hereinafter also referred to as a “conductive flat surface”) is decoupled electrically into the at least two blocks in the through hole. According to the wiring board of the present invention, the wiring board can be applied preferably in particular to the case where the flat surface in the through hole works as component connection lands, to which an electronic component is mounted via a conductive material such as solder. It is because the distance between the component connection land and the electronic component can be uniform. In other words, the process of melting and solidification of the conductive material such as solder can be performed uniformly, and hence it is possible to provide the wiring board with high quality and without a crack of solder or the like that may occur in the conventional example.

A method of manufacturing a wiring board according to the present invention includes: forming a hole having a flat surface in at least a part of the wiring board; forming a through hole by forming a conductive film on at least a part of the flat surface; and decoupling the flat surface electrically into at least two blocks.

According to the present invention, it is possible to obtain a superior effect that a wiring board having a structure different from the conventional structure and a manufacturing method therefor can be provided.

### BRIEF DESCRIPTION OF THE DRAWINGS

In the accompanying drawings:

FIG. 1A is a plan view illustrating a schematic structure of a wiring board according to a first embodiment;

FIG. 1B is a cross section of FIG. 1A cut along a line Ib-Ib;

FIG. 2A is a plan view for illustrating a manufacturing process of the wiring board according to the first embodiment;

FIG. 2B is a cross section of FIG. 2A cut along a line IIb-IIb;

FIG. 3A is a plan view for illustrating the manufacturing process of the wiring board according to the first embodiment;

FIG. 3B is a cross section of FIG. 3A cut along a line IIIb-IIIb;

FIG. 4A is a plan view for illustrating the manufacturing process of the wiring board according to the first embodiment;

FIG. 4B is a cross section of FIG. 4A cut along a line IVb-IVb;

FIG. 5A is a plan view for illustrating the manufacturing process of the wiring board according to the first embodiment;

FIG. 5B is a cross section of FIG. 5A cut along a line Vb-Vb;

FIG. 6A is a plan view for illustrating the manufacturing process of the wiring board according to the first embodiment;

FIG. 6B is a cross section of FIG. 6A cut along a line VIb-VIb;

FIG. 7A is a plan view for illustrating the manufacturing process of the wiring board according to the first embodiment;

FIG. 7B is a cross section of FIG. 7A cut along a line VIIb-VIIb;

FIG. 8A is a plan view for illustrating the manufacturing process of the wiring board according to the first embodiment;

FIG. 8B is a cross section of FIG. 8A cut along a line VIIIb-VIIIb;

FIG. 9A is a plan view for illustrating the manufacturing process of the wiring board according to the first embodiment;

FIG. 9B is a cross section of FIG. 9A cut along a line IXb-IXb;

FIG. 10A is a plan view of a component fixing tool according to the first embodiment;

FIG. 10B is a front view of the component fixing tool according to the first embodiment;

FIG. 10C is a side view of the component fixing tool according to the first embodiment;

FIG. 11 is a partially enlarged plan view of a portion including an electronic component and a component connection land according to the first embodiment;

FIG. 12A is a plan view illustrating a schematic structure of a wiring board according to a second embodiment;

FIG. 12B is a cross section of FIG. 12A cut along a line XIIb-XIIb;

FIG. 13A is a plan view illustrating a schematic structure of a wiring board according to a third embodiment;

FIG. 13B is a cross section of FIG. 13A cut along a line XIIIb-XIIIb;

FIG. 14 is a schematic cross section for illustrating a structure of a wiring board according to Conventional Example 1;

FIG. 15A is a cross section illustrating a schematic structure of a wiring board according to Conventional Example 2;

FIG. 15B is a plan view of a main portion of the wiring board according to Conventional Example 2; and

FIG. 16 is a partially enlarged plan view of the wiring board according to Conventional Example 2.

### DETAILED DESCRIPTION OF THE PREFERRED EMBODIMENTS

Hereinafter, an example of an embodiment to which the present invention is applied is described. Note that it is needless to say that other embodiments may also be in the scope of the present invention as long as they meet the spirit of the present invention.

### First Embodiment

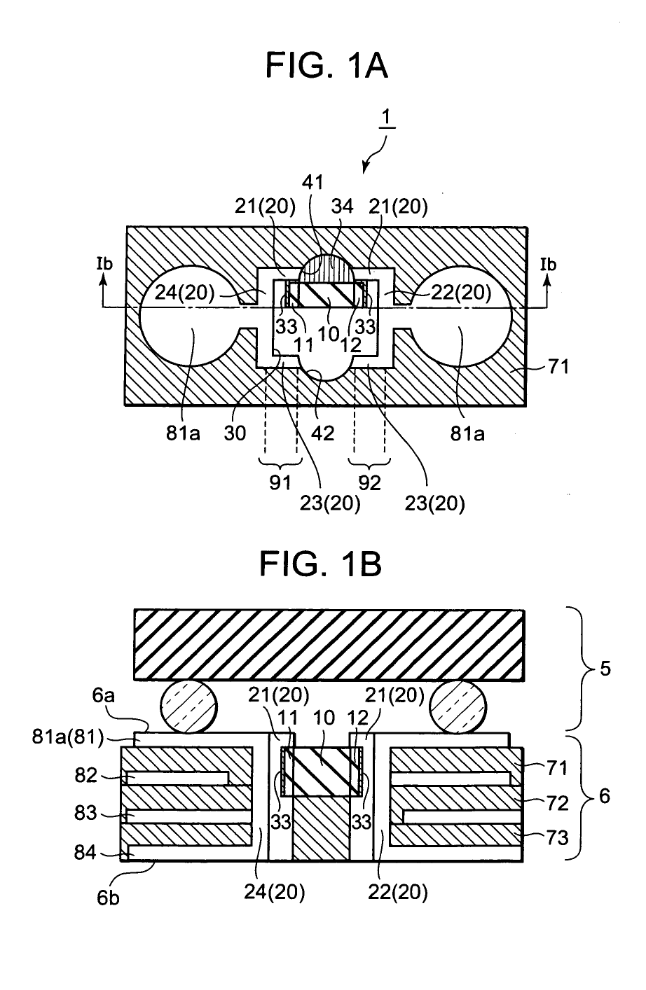

FIG. 1A is a plan view illustrating an example of a wiring board 1 according to a first embodiment, and FIG. 1B is a cross section of FIG. 1A cut along a line Ib-Ib. Note that a surface mount component 5 is not illustrated in FIG. 1A for convenience of description.

The wiring board 1 includes the surface mount component 5, a wiring substrate 6, an electronic component 10, and a through hole 30. The surface mount component 5 is mounted on the surface of the wiring substrate 6 as illustrated in FIG. 1B. The surface mount component 5 and the electronic component 10 are connected electrically to each other via terminals thereof. The electronic component 10 is embedded in the wiring substrate 6 so that the distance between the terminals of the electronic component 10 and the surface mount component 5 can be reduced. Hereinafter, structures of the respective components are described in detail.

The wiring substrate 6 is made up of three insulating layers and four wiring layers. The three insulating layers include specifically a first insulating layer 71, a second insulating layer 72 and a third insulating layer 73 arranged in this order from the top side. In addition, the four wiring layers include a first surface wiring layer 81, a first inner wiring layer 82, a second inner wiring layer 83 and a second surface wiring layer 84 arranged in this order from the top side. The first surface wiring layer 81 is formed on a first principal surface 6a of the wiring substrate 6, and the second surface wiring layer 84 is formed on a second principal surface 6b that is opposed to the first principal surface 6a. The first inner wiring layer 82 is an inner wiring layer disposed between the first insulating layer 71 and the second insulating layer 72. The second inner wiring layer 83 is an inner wiring layer disposed between the second insulating layer 72 and the third insulating layer 73.

The inner wiring layers including the first inner wiring layer 82 and the second inner wiring layer 83 are made up of copper foils that are patterned by an etching process. The first surface wiring layer 81 and the second surface wiring layer 84 formed on the first principal surface and the second principal surface of the wiring substrate 6 are made up of a patterned copper plating layer.

The through hole 30 is formed in the wiring substrate 6, and the through hole 30 pierces from the first principal surface 6a to the second principal surface 6b. A conductive layer 20 made of copper plating is formed on the wall surface of the through hole 30, and the conductive layer 20 is connected to a desired wiring layer. The through hole 30 according to the first embodiment has the structure of a substantially rectangular shape in plan view as illustrated in FIG. 1A. In other words, the wall surface of the through hole 30 is made up of four conductive flat surfaces that are substantially orthogonal to the first principal surface 6a and the second principal surface 6b of the wiring substrate 6. Here, the flat surface on the upper side of the wall surface of the through hole 30 of FIG. 1A is referred to as a first flat surface 21, and the flat surface on the right side of the wall surface of the through hole 30 of FIG. 1A is referred to as a second flat surface 22. In the same manner, the flat surface on the lower side is referred to as a third flat surface 23, and the flat surface on the left side is referred to as a fourth flat surface 24.

Among the four flat surfaces of the wall surface of the through hole 30, the first flat surface 21 is provided with a first through groove 41 decoupling the flat surface electrically. In other words, a stripe-like groove is formed along the extending direction of the through hole. In addition, in the same manner, the third flat surface 23 that is opposed to the first flat surface 21 is provided with a second through groove 42 decoupling the third flat surface 23 electrically. The first through groove 41 and the second through groove 42 divide the conductive layer 20 formed on the wall surface of the through hole 30 into two conductive blocks. Here, the conductive block on the left side of FIG. 1A is referred to as a first conductive block 91, and the conductive block on the right side of FIG. 1A is referred to as a second conductive block 92.

Note that the “through hole” herein includes one that pierces at least one set of neighboring wiring layers in the lamination direction of the wiring layers among the plurality of wiring layers. The through hole according to the first embodiment may be a hole portion that pierces the first surface wiring layer 81 and the first inner wiring layer 82 instead of one that pierces from the first principal surface to the second principal surface.

The first surface wiring layer 81 formed on the first principal surface 6a of the wiring substrate 6 is provided with two patterns of mounting lands 81a for mounting the surface mount component 5, which are formed at the positions opposed to each other via the through hole 30 (see FIG. 1A). The surface mount component 5 is mounted on the two mounting lands 81a as illustrated in FIG. 1B, and the wiring substrate 6 is connected to the surface mount component 5 electrically via the mounting land 81a.

The electronic component 10 is embedded in the through hole 30 that is formed in the wiring substrate 6. Each of the left and right ends of the electronic component 10 of FIG. 1B is provided with a terminal. The terminal of the electronic component 10 on the left side in the figure is referred to as a first terminal 11, and the terminal on the right side in the figure is referred to as a second terminal 12. The electronic component 10 according to the first embodiment may be any type as long as the electronic component 10 has at least a terminal that can be connected to the wiring substrate 6 and a size with which the electronic component 10 can be embedded. As an example, the electronic component 10 may be a chip type capacitor, an inductor, a diode or a resistor element. Otherwise, the electronic component 10 may be a chip type transistor, a bare semiconductor chip, or a semiconductor device housed in a package.

The electronic component 10 is fixed onto the first flat surface 21 of the through hole 30 and is connected electrically to the same as illustrated in FIG. 1A. More specifically, the first terminal 11 of the electronic component 10 is connected electrically to the first flat surface 21 on the side of the first conductive block 91 via cream solder 33. In the same manner, the second terminal 12 of the electronic component 10 is connected electrically to the first flat surface 21 on the side of the second conductive block 92 via the cream solder 33. Note that the electronic component 10 and the wiring substrate 6 are fixed by adhesive 34 filled in the first through groove 41 and the cream solder 33.

The surface mount component 5 and the electronic component 10 are connected to each other electrically via the mounting land 81a formed on the first surface wiring layer 81 of the wiring substrate 6 and the conductive layer 20 of the through hole 30 formed in the wiring substrate 6. By adopting the structure described above, the connection distance between the surface mount component 5 and the electronic component 10 can be short.

In addition, the connection region of the through hole 30 that is connected to the electronic component 10 is made the conductive flat surface, and hence a facing distance between the terminal of the electronic component and the flat surface of the through hole can be constant. Therefore, the process of melting and solidification of the solder at the portion can be uniformed. As a result, a wiring board with high quality can be provided. In addition, the solder poor connection can be prevented, and hence it is possible to improve manufacturing yield greatly.

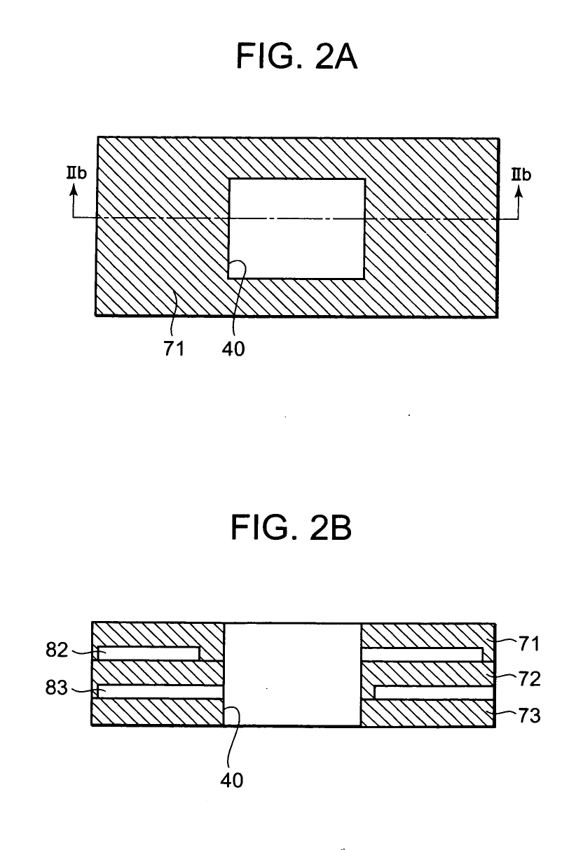

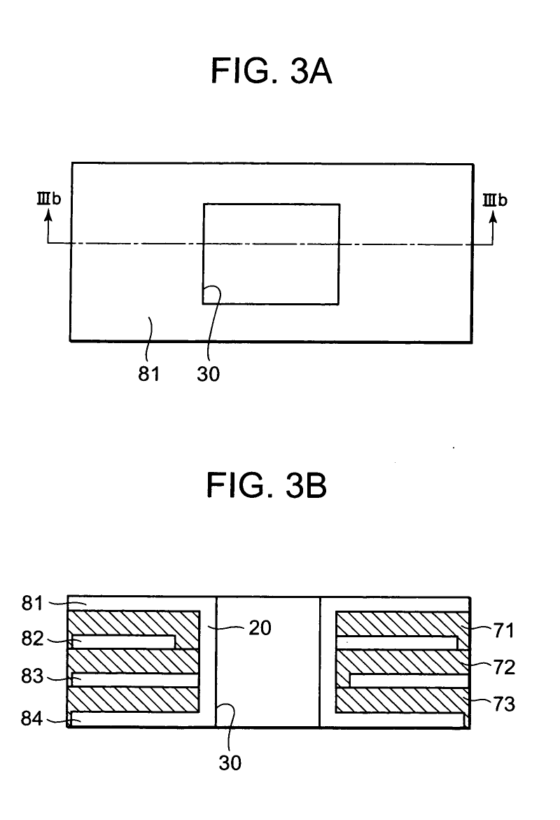

Next, a manufacturing method for the wiring board according to the first embodiment is described with reference to FIGS. 2A to 9B. FIGS. 2A, 3A, . . . and 9A are plan views illustrating the manufacturing process of the wiring board according to the first embodiment while FIGS. 2B, 3B, . . . and 9B are cross sections of FIGS. 2A, 3A, . . . and 9A, respectively.

The wiring substrate having the above-mentioned insulating layers and wiring layers is manufactured in accordance with a known manufacturing process. A component mounting hole 40 is formed in the obtained wiring substrate for forming the through hole 30 (see FIGS. 2A and 2B). The component mounting hole 40 is formed so as to have a rectangular shape in plan view. In other words, the component mounting hole 40 includes four flat surfaces.

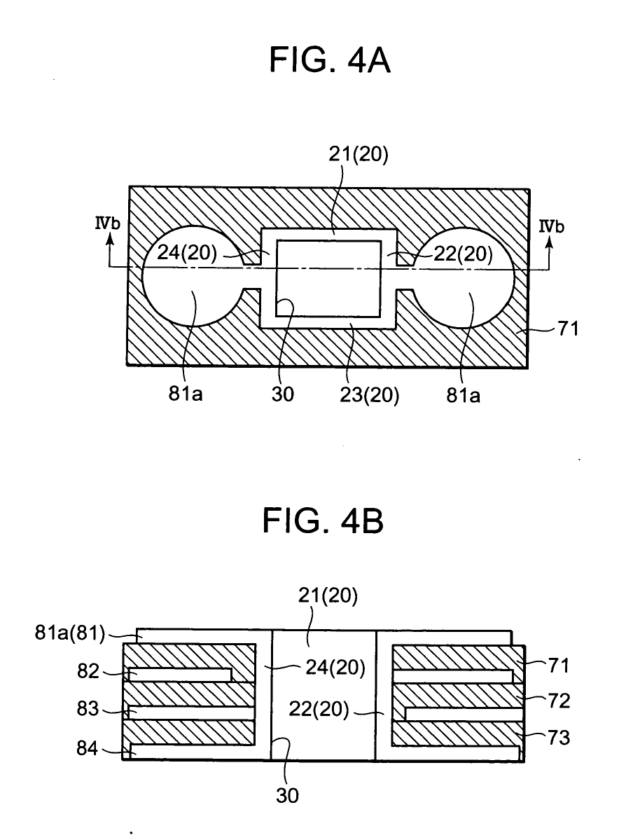

Next, the conductive layer 20 is formed on the surface of the component mounting hole 40 by a plating method so that the through hole 30 is formed. Thus, the through hole 30 that pierces the wiring substrate and has a conductive flat surface is formed. In addition, at the same time, the first surface wiring layer 81 is formed on the first principal surface of the wiring substrate while the second surface wiring layer 84 is formed on the second principal surface of the wiring substrate (see FIGS. 3A and 3B). Then, the first surface wiring layer 81 and the second surface wiring layer 84 are processed by a conventional method such as etching or the like so that desired patterns of wiring layers are formed. On this occasion, the mounting land 81a for mounting the surface mount component 5 is also formed together on the first surface wiring layer 81 (see FIGS. 4A and 4B).

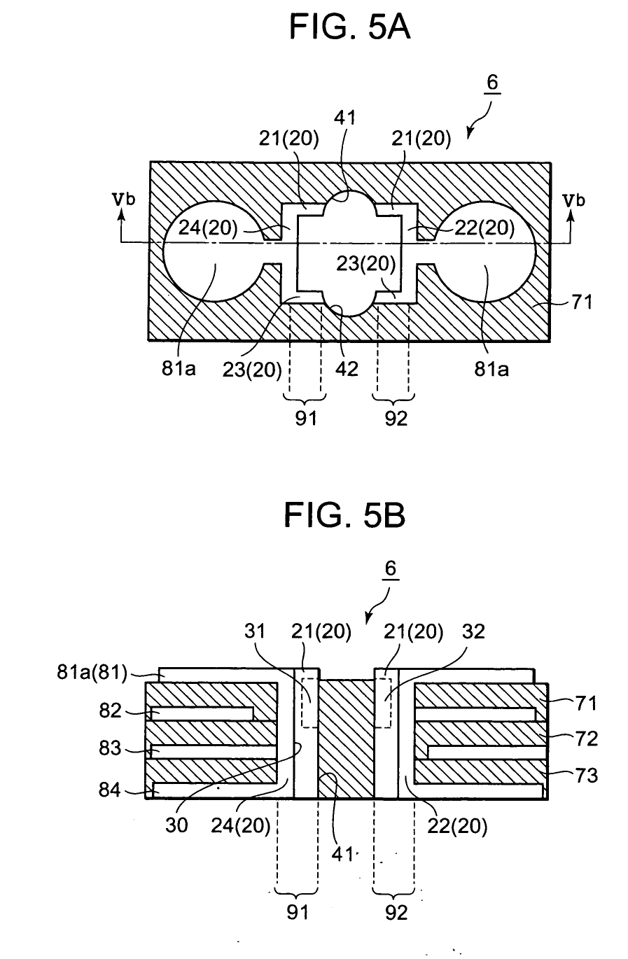

Next, the first through groove 41 like a stripe is formed on the first flat surface 21 of the through hole 30 so as to decouple the conductive layer 20. Similarly, the second through groove 42 like a stripe is formed on the third flat surface 23 that is opposed to the first flat surface 21 so as to decouple the conductive layer 20. The first through groove 41 and the second through groove 42 decouple the conductive layer 20 formed on the surface of the through hole 30 into two conductive blocks. In other words, the conductive layer 20 is decoupled into the first conductive block 91 and the second conductive block 92. Thus, the wiring substrate 6 is completed (see FIGS. 5A and 5B).

Each of the first conductive block 91 and the second conductive block 92 is provided with a connection land for connecting to the terminal of the electronic component 10. The region indicated by the dotted line of FIG. 5B of the first conductive block 91 on the first flat surface 21 is referred to as a first component connection land 31 for connecting to the first terminal 11 of the electronic component 10. In the same manner, the region indicated by the dotted line of FIG. 5B of the second conductive block 92 on the first flat surface 21 is referred to as a second component connection land 32 for connecting to the second terminal 12 of the electronic component 10.

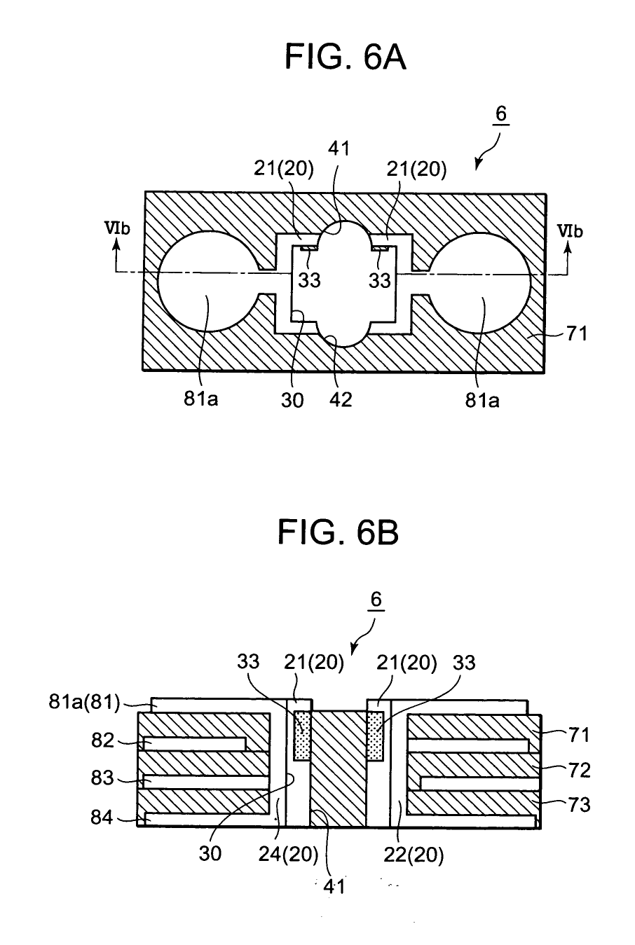

After that, the cream solder 33 is applied to the first component connection land 31 located at the position for connecting to the first terminal 11 of the electronic component 10 in the through hole 30. In the same manner, the cream solder 33 is applied to the second component connection land 32 located at the position for connecting to the second terminal 12 of the electronic component 10 in the through hole 30 (see FIGS. 6A and 6B).

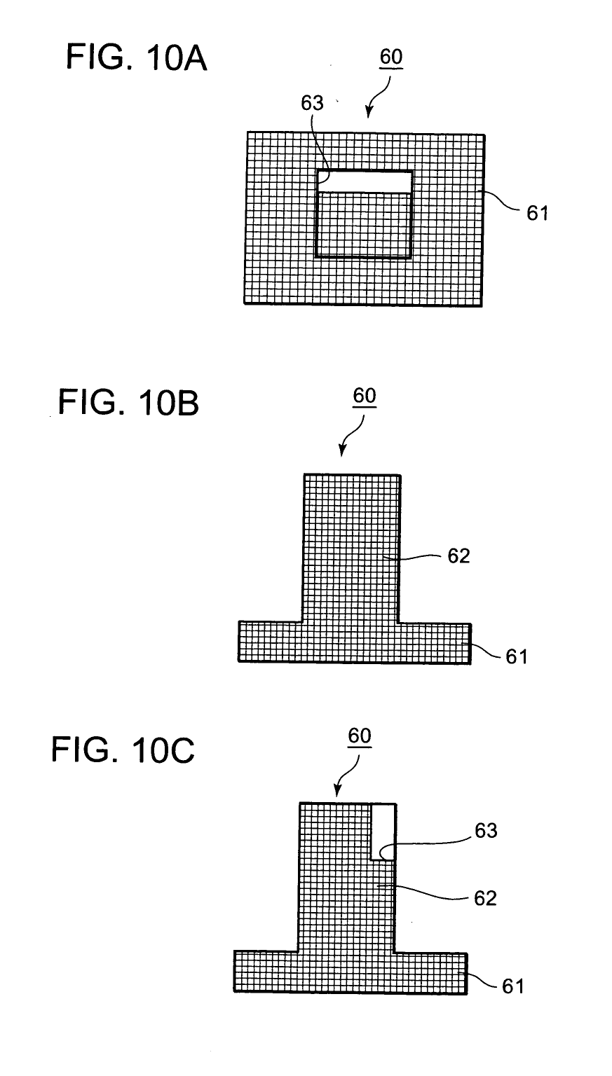

After the cream solder 33 is applied, a component fixing tool 60 is set to the wiring substrate 6. FIG. 10A is a plan view of the component fixing tool 60. FIG. 10B is a front view of the component fixing tool 60, and FIG. 10C is a side view of the component fixing tool 60. The component fixing tool 60 includes a support portion 61, an insert portion 62, and a notch portion 63. The support portion 61 has a role of keeping stability when the wiring substrate 6 is set. The insert portion 62 has maximum dimensions with which the component fixing tool 60 can be inserted in the through hole of the wiring substrate 6 and has a role of holding the electronic component 10 together with the notch portion 63 that is formed on the distal end portion of the insert portion 62.

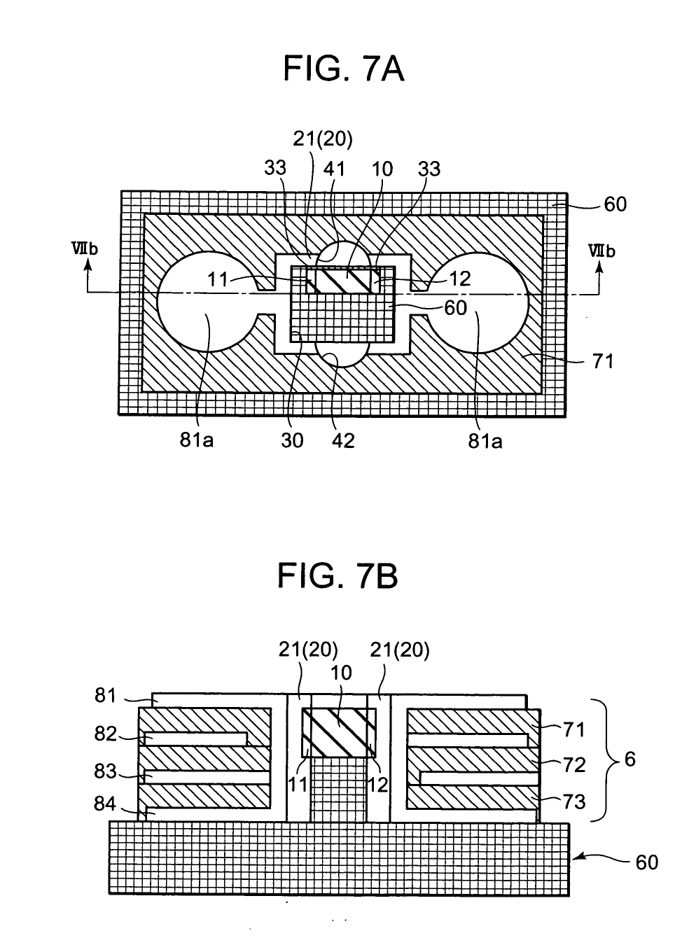

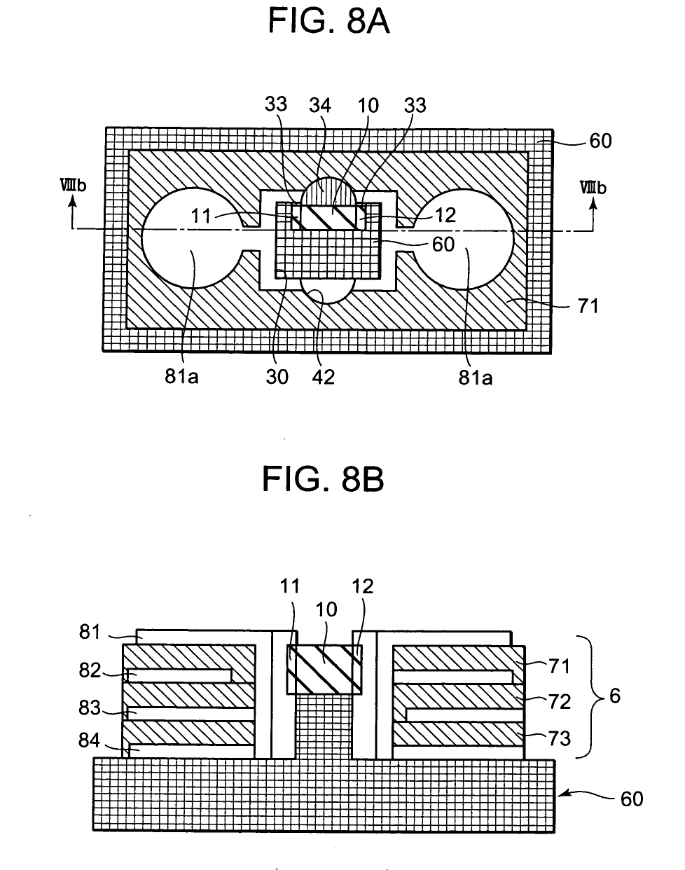

The component fixing tool 60 having the structure described above is attached to the wiring substrate 6 from the second principal surface 6b, and then the electronic component 10 is mounted from the side of the first principal surface 6a of the wiring substrate 6 (see FIGS. 7A and 7B). Next, a gap portion between the electronic component 10 and the first through groove 41 is filled with the adhesive 34 so that the electronic component 10 is fixed to the wiring substrate 6 (see FIGS. 8A and 8B).

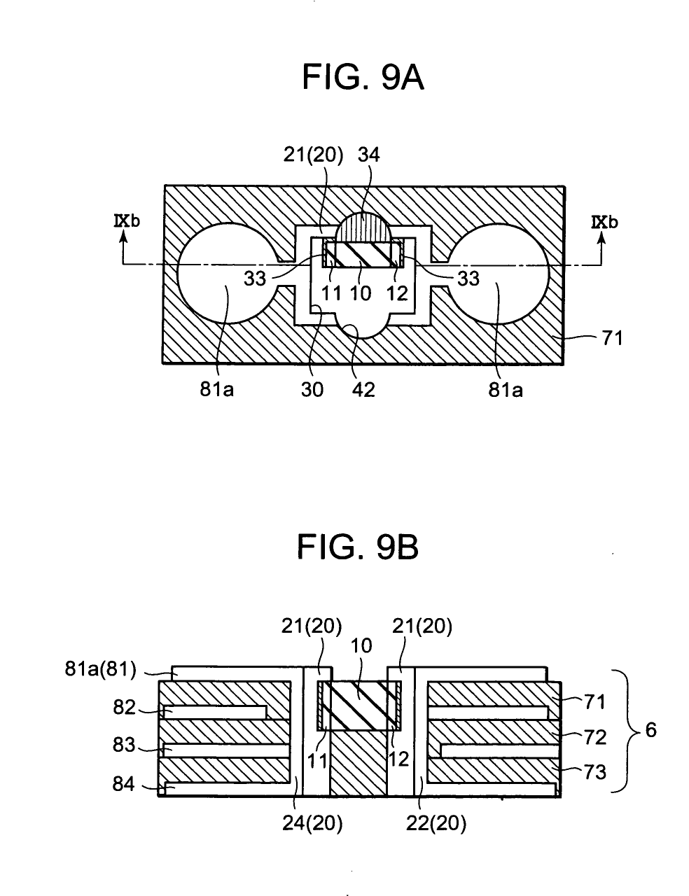

After the electronic component 10 is fixed to the wiring substrate 6, the component fixing tool 60 is removed, and heated air is passed through the through hole 30so that the cream solder 33 is melted. Thus, the first terminal 11 of the electronic component 10 and the first component connection land 31 are connected to each other electrically via the cream solder 33. In the same manner, the second terminal 12 of the electronic component 10 and the second component connection land 32 are connected to each other via the cream solder 33 (see FIGS. 9A and 9B).

The surface mount component 5 is further mounted on the wiring substrate 6 on which the electronic component 10 is mounted, and the wiring board 1 illustrated in FIG. 1 is obtained. The surface mount component 5 is placed on the two mounting land 81a formed on the first surface wiring layer 81 as described above. The mounting land 81a on the left side of FIG. 1B and the first component connection land 31 are connected to each other electrically while the connection land 81a on the right side of FIG. 1B and the second component connection land 32 are connected to each other electrically. Thus, the electronic component 10 and the surface mount component are connected to each other electrically.

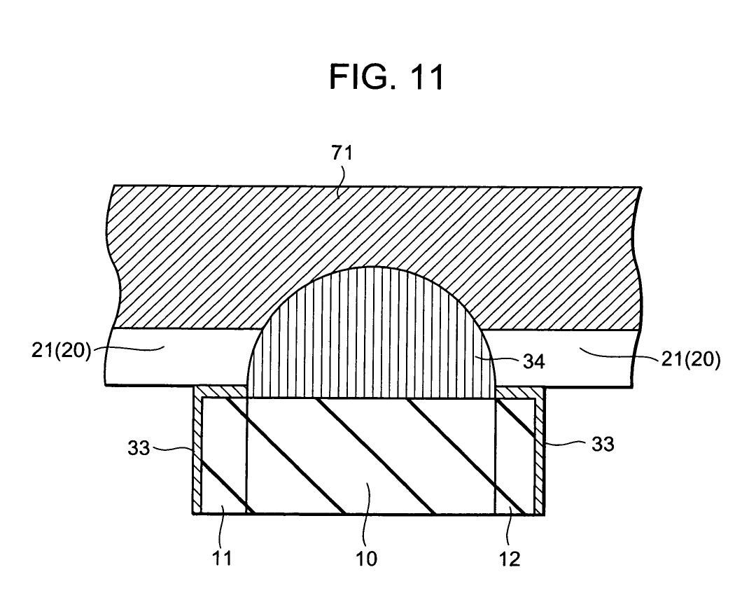

FIG. 11 illustrates a partially enlarged plan view of a portion including opposed regions of the electronic component 10 and the first flat surface 21. The electronic component 10 and the first flat surface 21 are fixed by the adhesive 34 and the cream solder 33 as described above. Then, the electronic component 10 and the first flat surface 21 are connected to each other electrically via the cream solder 33. According to the first embodiment, the thickness of the cream solder between the first flat surface 21 and the first terminal 11 of the electronic component 10 that are opposed to each other is substantially uniform. The same is true for the cream solder between the first flat surface 21 and the second terminal 12 of the electronic component 10. Thus, when the solder is melted in a reflow furnace, the melted state can be uniform. As a result, the occurrence of a crack in the solder can be suppressed, and hence the solder poor connection can be prevented.

Note that a thin film of the cream solder 33 is formed also on the surface adjacent to the surface of the first terminal 11 of the electronic component 10 that is disposed so as to face the first flat surface 21 as illustrated in FIG. 11. This coat is formed by the solder that is melted in the reflow furnace and flows by capillary action. Therefore, the coat is an extremely thin film. For this reason, the coat does not cause a crack in the solder due to the melted state of the solder.

According to the first embodiment, it is possible to provide the wiring board that can suppress the solder poor connection by the simple method of forming the through groove on the conductive flat surface of the through hole. Therefore, the manufacturing yield can be enhanced. In addition, the conductive flat surface of the through hole 30 is divided by the through groove, and hence the component connection lands having the flat portions are formed so that the first terminal 11 of the electronic component 10 and the first component connection land 31 are arranged to have a substantially uniform distance between the first terminal 11 and the first component connection land 31. In the same manner, the second terminal 12 of the electronic component 10 and the second component connection land 32 are arranged to have a substantially uniform distance between the second terminal 12 and the second component connection land 32. Thus, a temperature difference at the connecting part is decreased, and the state of the melted solder is made uniform so that the wiring board having high quality can be provided. In addition, the manufacturing yield can be enhanced by solving the problem of the solder poor connection.

### Second Embodiment

Next, an example of a component embedded wiring board that is different from the first embodiment is described. Note that, in the following description, element members that are respectively the same as those in the first embodiment are denoted by the same reference symbols so that the descriptions thereof are omitted appropriately.

The fundamental structure of the component embedded wiring board according to a second embodiment is the same as that of the first embodiment described above except for the followings. In contrast to the first embodiment described above in which the shape of the through hole is the rectangular shape in plan view, the shape of the through hole in plan view of the second embodiment is made up of a flat surface and a curved surface.

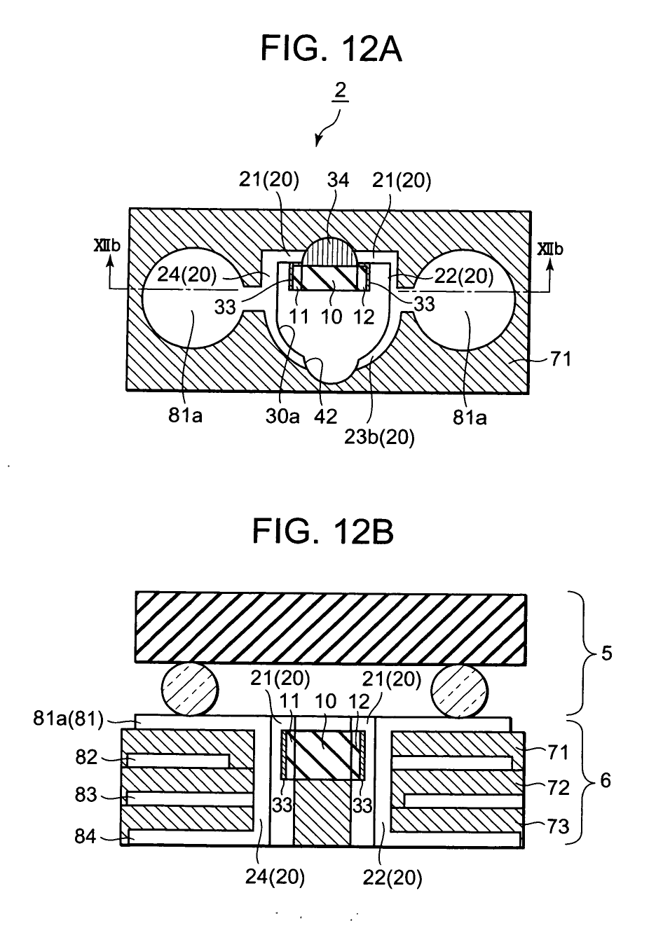

FIG. 12A is a schematic plan view for illustrating an example of the wiring board according to the second embodiment, and FIG. 12B is a cross section of FIG. 12A cut along a line XIIb-XIIb. Note that the surface mount component 5 is not illustrated in FIG. 12A for convenience of description.

As illustrated in FIGS. 12A and 12B, the inner wall of a through hole 30a formed in a component embedded wiring board 2 according to the second embodiment is made up of a flat surface and a curved surface. The inner wall of the through hole 30a is made up of the first flat surface 21 located on the upper side of the through hole of FIG. 12A, the second flat surface 22 located on the right side of FIG. 12A, the fourth flat surface 24 located on the left side of FIG. 12A, and a curved surface 23b of a substantially semicircle shape of FIG. 12A in plan view. Each of the surfaces is substantially orthogonal to the first principal surface 6a and the second principal surface 6b of the wiring substrate 6.

The first through groove 41 is formed on the first flat surface 21 as the wall surface of the through hole 30a so as to decouple the flat surface electrically. In addition, the second through groove 42 is formed similarly on the curved surface 23b located to be opposed to the first flat surface 21 so as to decouple the curved surface 23b electrically. The first through groove 41 and the second through groove 42 divide the conductive layer 20 formed on the wall surface of the through hole 30a into two conductive blocks (first conductive block 91 and second conductive block 92).

The electronic component 10 is fixed to the first flat surface 21 of the through hole 30a and is connected to the same electrically. More specifically, the first terminal 11 of the electronic component 10 is connected electrically to the first flat surface 21 on the side of the first conductive block 91 via the cream solder 33. In the same manner, the second terminal 12 of the electronic component 10 is connected electrically to the first flat surface 21 on the side of the second conductive block 92 via the cream solder 33. Note that the electronic component 10 and the wiring substrate 6 are fixed by the adhesive 34 filled in the first through groove 41 and the cream solder 33.

According to the wiring board 2 of the second embodiment, the same effect as that of the first embodiment described above can be obtained. It is sufficient that the through hole has the shape in which at least the region connected to the terminal of the electronic component is the flat surface, and the shape can be modified variously within the scope of the present invention without deviating from the spirit thereof. Therefore, the shape and the form of the through hole can be selected flexibly in accordance with a usage and a purpose.

### Third Embodiment

The fundamental structure of a component embedded wiring board according to a third embodiment is the same as that of the first embodiment described above except for the followings. In contrast to the first embodiment described above in which the terminals of the electronic component 10 are connected to the first flat surface 21 electrically, the terminals of the electronic component in the third embodiment are connected to the first flat surface 21, the second flat surface 22 and the fourth flat surface 24 electrically.

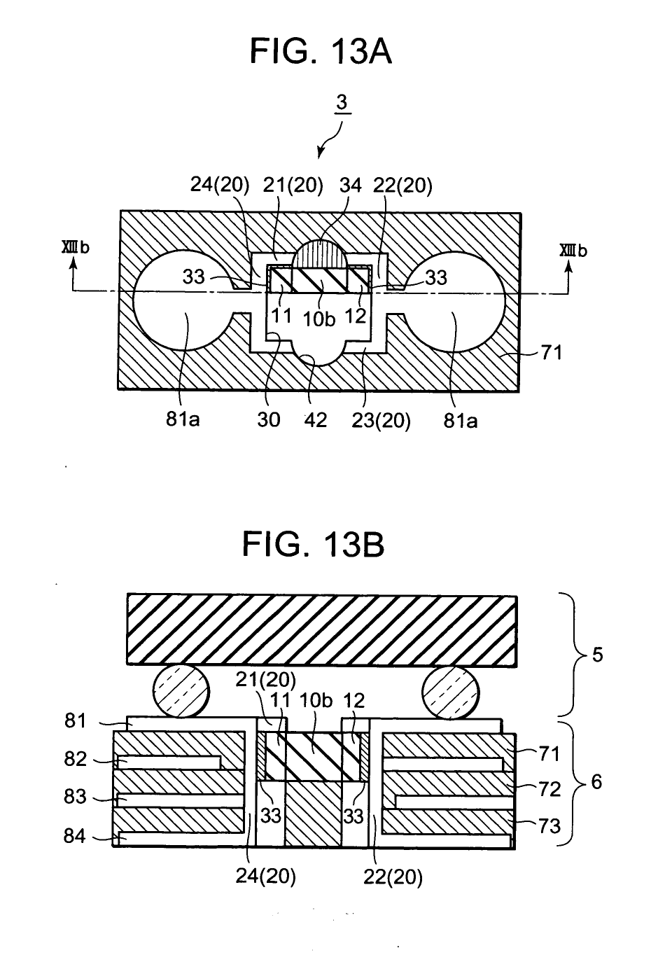

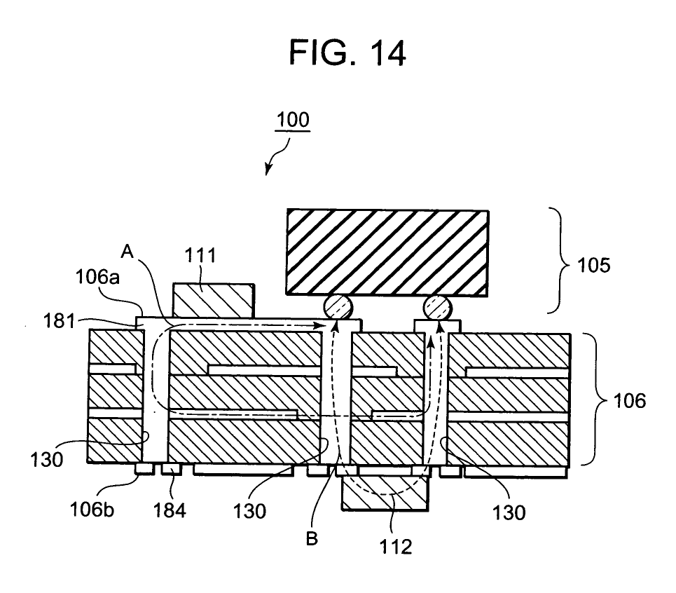

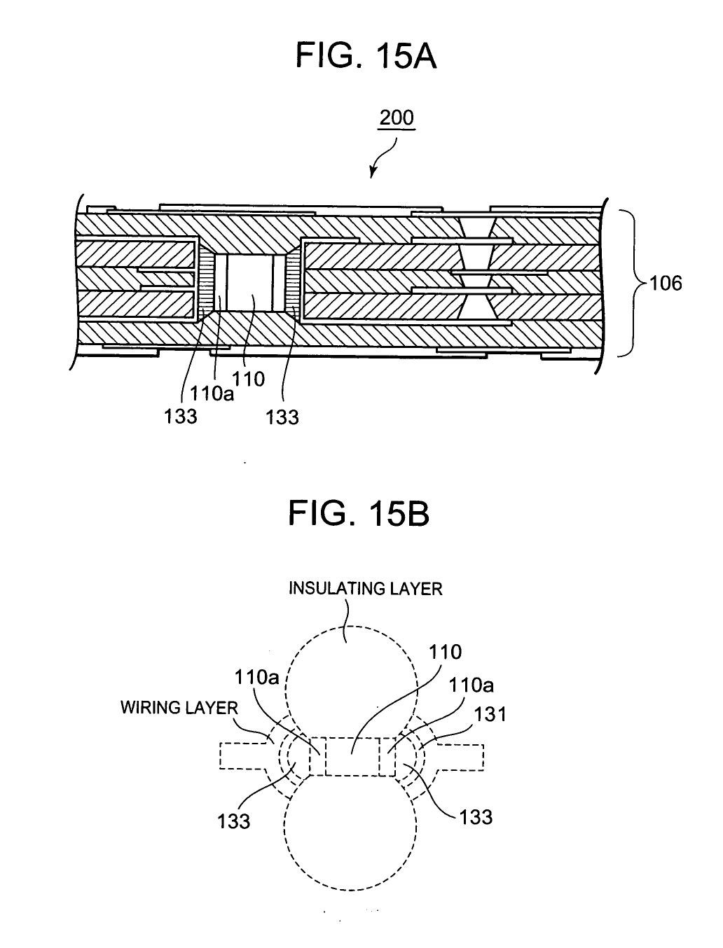

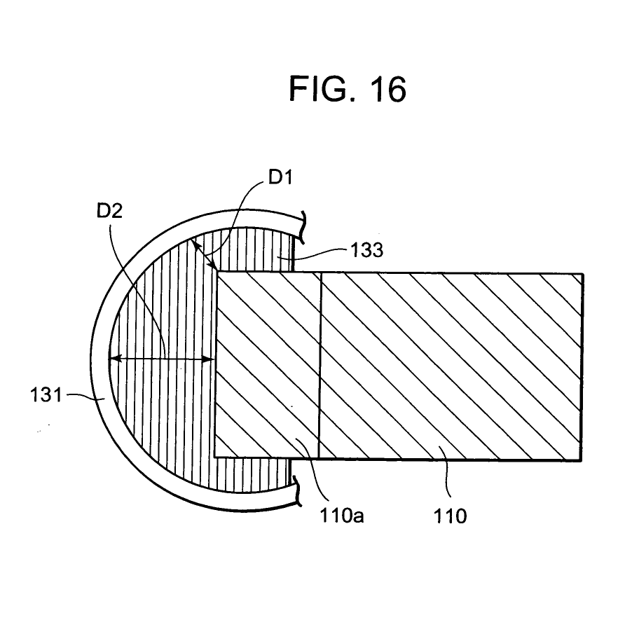

FIG. 13A is a schematic plan view for illustrating an example of a wiring board 3 according to the third embodiment, and FIG. 13B is a cross section of FIG. 13A cut along a line XIIIb-XIIIb. Note that the surface mount component 5 is not illustrated in FIG. 13A for convenience of description.

As illustrated in FIGS. 13A and 13B, an electronic component 10b of the third embodiment is connected to the three flat surfaces (first flat surface 21, second flat surface 22 and fourth flat surface 24) of a through hole 30b via the cream solder 33.

According to the third embodiment, the same effect as the embodiments described above can be obtained. In addition, it is possible to obtain the merit that the contact area between the terminal of the electronic component and the connection land on the inner wall of the through hole can be increased while a size of the through hole is the same as those in the embodiments described above.

The wiring board according to the present invention is sufficient to have the through hole as follows, and can be modified variously within the scope of the present invention without deviating from the spirit thereof. More specifically, it is sufficient that the wiring board includes a plurality of wiring layers and a through hole piercing at least one set of neighboring wiring layers in the lamination direction of the wiring layers, and that a flat surface having conductivity is formed on the surface of the through hole at least partially, and the flat surface is decoupled electrically into at least two blocks.

The first to third embodiments describe the wiring board having a structure in which the electronic component is mounted in the through hole, and the surface mount component is mounted on the surface of the wiring board, but the present invention can be applied to a wiring board in which no electronic component is mounted. In addition, the present invention can be applied to a wiring board on which no surface mount component is mounted. In other words, in the example of FIGS. 1A and 1B, the surface mount component 5 and the electronic component 10 may be removed from the wiring board 1 so that the wiring substrate 6 itself can be used as the wiring board. According to the present invention, it is possible to provide the wiring board having a new structure different from that of the wiring board according to the conventional example.

In addition, the embodiments described above exemplify the structure in which the through hole pierces from the first principal surface to the second principal surface, but the present invention can be applied also to the through hole that pierces at least one set of neighboring wiring layers among the plurality of wiring layers in the lamination direction of the wiring layers as described above. In addition, the example of forming the through groove as a method of decoupling the flat surface of the wall surface of the through hole electrically into at least two blocks is described above, but this structure should not be interpreted in a limited manner. The method is not limited to a particular form as long as it can decouple the flat surface electrically.

In addition, the first to third embodiments described above use the example in which one electronic component is mounted, but this structure should not be interpreted in a limited manner. A plurality of electronic components can be mounted in one through hole as necessary. According to the present invention, the component connection lands are formed on the flat surface of the through hole by a simple method of decoupling the same electrically. Therefore, it is also easy to mount electronic components having different sizes or different shapes in one through hole. It is needless to say that the number of the through holes piercing the wiring board is not limited to one. In addition, other structural components such as a lead wire of the surface mount component may be inserted in the through hole.

It is sufficient to adopt the structure in which the inner wall of the through hole has a flat surface at least in the region connecting to the terminal of the electronic component, and the terminals of the electronic component are connected to different conductive blocks. The structure may be modified variously in the scope of the present invention without deviating from the spirit thereof. In addition, the example is described in which the flat surface on the inner wall of the through hole is substantially orthogonal to the first principal surface and the second principal surface of the wiring board, but this structure should not be interpreted in a limited manner and may be modified as necessary.

The structure is exemplified in which the cream solder is used as means for connecting the component connection land in the through hole with the electronic component, but any material having conductivity can be used without limitation. For instance, conductive paste or the like can be used preferably.

What is claimed is:

1. A wiring board, comprising:
a first principal surface;
a second principal surface being opposed to the first principal surface;
a plurality of wiring layers; and
a through hole piercing at least one set of neighboring wiring layers among the plurality of wiring layers in a lamination direction of the at least one set of neighboring wiring layers,
wherein the through hole comprises a flat surface that has conductivity and is decoupled electrically into at least two blocks formed on its surface at least partially.

2. A wiring board according to claim 1, wherein the flat surface is substantially orthogonal to the first principal surface and the second principal surface.

3. A wiring board according to claim 1, wherein the through hole pierces from the first principal surface to the second principal surface.

4. A wiring board according to claim 1, wherein the through hole has a substantially rectangular shape in plan view.

5. A wiring board according to claim 1, wherein the at least two blocks of the flat surface that are decoupled electrically are lands for mounting an electronic component and for connecting the electronic component electrically.

6. A wiring board according to claim 5, wherein the electronic component is mounted in the through hole and is connected to the lands electrically.

7. A wiring board according to claim 6, wherein the electronic component is connected to the lands electrically via solder.

8. A wiring board according to claim 5, wherein the electronic component is one of a capacitor, a resistor element, an inductor, a diode, and a transistor.

9. A wiring board according to claim 5, wherein the electronic component is one of a bare semiconductor chip and a semiconductor device housed in a package.

10. A wiring board according to claim 1, wherein the flat surface is decoupled electrically into the at least two blocks by a groove.

11. A method of manufacturing a wiring board, comprising:
forming a hole having a flat surface in at least a part of the wiring board;
forming a through hole by forming a conductive film on at least a part of the flat surface; and
decoupling the flat surface electrically into at least two blocks.

12. A method of manufacturing a wiring board according to claim 11, further comprising:
mounting an electronic component in the through hole after the decoupling the flat surface electrically into the at least two blocks; and
fixing the electronic component to the at least the part of the flat surface having conductivity, and connecting the electronic component and the at least the part of the flat surface to each other electrically.

13. A method of manufacturing a wiring board according to claim 12, further comprising:
applying solder onto at least a part of the flat surface before the mounting the electronic component; and
melting the solder after the mounting the electronic component in the through hole to connect the electronic component to the flat surface electrically.
